(19) United States
(12) Patent Application Publication
(10) Pub. No.: US 2025/0048737 A1
(43) Pub. Date: Feb. 6, 2025

(54) ARRAY SUBSTRATE, DISPLAY PANEL AND DISPLAY APPARATUS

(71) Applicants: Chongqing BOE Optoelectronics Technology Co., Ltd., Chongqing (CN); BOE Technology Group Co., Ltd., Beijing (CN)

(72) Inventors: Zhongshan WU, Beijing (CN); Xiaoyuan WANG, Beijing (CN); Kun YANG, Beijing (CN); Yuanyuan PENG, Beijing (CN); Yan LIU, Beijing (CN); Hao SUN, Beijing (CN); Jing CAO, Beijing (CN)

(21) Appl. No.: 18/776,332

(22) Filed: Jul. 18, 2024

Related U.S. Application Data
(63) Continuation of application No. PCT/CN2023/110967, filed on Aug. 3, 2023.

(51) Int. Cl. H01L 27/12

(52) U.S. Cl. CPC H01L 27/1244

(57) ABSTRACT

Disclosed are an array substrate, a display panel and a display apparatus. The array substrate includes: at least one pad group located in a bonding area, and the pad group including a plurality of pads arranged sequentially along a second direction; at least one connection line group disposed on the same side of a substrate as a plurality of data lines in the bonding area, and the connection line group including a plurality of connection lines, an end of a connection line being electrically connected to a data line, and other end of the connection line being electrically connected to a pad, and connection lines of a same connection line group being electrically connected to a same pad group. In the connection line group, multiple connection lines located on at least one side of the pad group are arranged in multiple wiring regions along the second direction.

### CROSS REFERENCE TO RELATED APPLICATIONS

The disclosure is a continuation application of International Application No. PCT/CN2023/110967, filed Aug. 3, 2023, the entire content of which is incorporated herein by reference.

### TECHNICAL FIELD

The disclosure relates to the field of a semiconductor technology, and particularly relates to an array substrate, a display panel and a display apparatus.

### BACKGROUND

With the development of information technology, electronic devices have become widely used in people's daily lives. Liquid crystal displays, as one of the most widely used flat-panel displays, hold a crucial position in display panels. Currently, the notebook market increasingly pursues low cost and high display performance, requiring optimization in the design of display screens. The source chip of the display screen incurs relatively high costs. In the current majority of products, a single gate design is employed. With adoption of a dual gate design, the number of source chips used per screen is reduced by half, significantly reducing the original cost of the product. However, existing products with dual gate designs may exhibit black block (Block) display defects or split-screen display defects (as shown in the dashed box in FIG. 1).

### SUMMARY

Embodiments of the disclosure provide an array substrate, a display panel and a display apparatus.

The array substrate includes a display area and a bonding area on a side of the display area and includes:
a substrate;
a plurality of data lines disposed on a side of the substrate in the display area and extending along a first direction;
at least one pad group disposed on a same side of the substrate as the plurality of data lines in the bonding area, and the pad group including a plurality of pads arranged sequentially along a second direction;
at least one connection line group disposed on the same side of the substrate as the plurality of data lines in the bonding area, and the connection line group including a plurality of connection lines, an end of a connection line being electrically connected with a data line, and the other end of the connection line being electrically connected with a pad, and connection lines of a same connection line group being electrically connected with a same pad group. In the connection line group, multiple connection lines located on at least one side of the pad group are arranged in multiple wiring regions along the second direction; in a same wiring region, a line width of each connection line is approximately equal; and in a direction from a connection line at an outermost edge of the connection line group to the pad group, line widths of connection lines in the multiple wiring regions decrease.

In a possible implementation, in the direction from the connection line at the outermost edge of the connection line group to the pad group, line spacings between the connection lines in the multiple wiring regions decrease.

In a possible implementation, a line width indicated as W and a line spacing indicated as S between two adjacent connection lines in each wiring region satisfy a following relationship:

$$W = \frac{2 fn ( G + S )}{3 km} - S ;$$

where k indicates a sequential index of the wiring regions in a direction from an edge of the connection line group to the pad group, f indicates the quantity of wiring regions in the direction from the edge of the connection line group to the pad group, m indicates a display resolution along the second direction of the array substrate, n indicates the quantity of pad groups, and G indicates a maximum width of the wiring region along the first direction.

In a possible implementation, the line width indicated as W of the connection line and the line spacing indicated as S between the two adjacent connection lines further satisfy a following relationship:

$$15 \% \leq \frac{S}{W + S} \leq 50 \% .$$

In a possible implementation, a line width difference between connection lines of any two adjacent wiring regions is equal.

In a possible implementation, in the direction from the connection line at the outermost edge of the connection line group to the pad group, the quantity of connection lines in the multiple wiring regions increase.

In a possible implementation, in the direction from the connection line at the outermost edge of the connection line group to the pad group, lengths of the multiple wiring regions on the second direction are equal or increase.

In a possible implementation, along the second direction, the quantity indicated as H of connection lines in a wiring region farthest from the pad group satisfies a following relationship:

$$H = \frac{3 m}{2 n \times f} ;$$

where f indicates a quantity of wiring regions in the direction from the edge of the connection line group to the pad group, m indicates a display resolution along the second direction of the array substrate, and n indicates the quantity of pad groups.

In a possible implementation, in the direction from the connection line at the outermost edge of the connection line group to the pad group, the quantity of connection lines in adjacent wiring regions is increased by H in turn.

In a possible implementation, in the direction from the connection line at the outermost edge of the connection line group to the pad group, a length indicated as d of each wiring region along the second direction satisfies a following relationship: d=H*P; where P indicates a width of a sub-pixel on the array substrate in the second direction.

In a possible implementation, the wiring region includes a first sub-wiring region and a second sub-wiring region located on a side of the first sub-wiring region facing the display area, and connection lines in the second sub-wiring region extend along the first direction. In the direction from the connection line at the outermost edge of the connection line group to the pad group, a ratio of a second sub-wiring region to a wiring region including the second sub-wiring regions gradually decrease.

In a possible implementation, a line resistance indicated as R_{fmax} of the connection line at the outermost edge satisfies a following relationship:

$${R}_{fmax} \leq \frac{7 \times {R}_{aa}}{13} + \frac{20 \times {R}_{fmin}}{13} ;$$

where Rₐₐ indicates a resistance of the data line, and R_{fmin} indicates a resistance of a connection line extending along the first direction between the pad group and the display area.

In a possible implementation, the array substrate further includes a junction region between adjacent wiring regions, where the junction region includes junction lines electrically connected one-to-one with at least part of the connection lines in the adjacent wiring regions, and an extension direction of the junction lines intersect with an extension direction of the connection lines.

In a possible implementation, an included angle indicated as a formed between the junction line and the second direction ranges from 30° to 65°.

In a possible implementation, a line width of the junction lines is the same as a line width of connection lines in an adjacent wiring region on a side away from the pad group. A line spacing of the junction lines is the same as a line spacing of the connection lines in the adjacent wiring region on the side away from the pad group.

In a possible implementation, in the direction from the connection line at the outermost edge of the connection line group to the pad group, minimum widths of at least two adjacent wiring regions in the first direction increase.

In a possible implementation, a shape of the connection line in at least part of a position where the connection line is electrically connected with the data line is bent. A shape of the connection line in at least part of a position where the connection line is electrically connected with the pad group is bent.

In a possible implementation, the shape of the connection line at the position where the connection line is electrically connected with the data line includes an S-shape, a shape like Chinese character “ [symbol] ”, or a folded line shape.

In a possible implementation, the connection line includes a main connection line, a first auxiliary connection line electrically connected with the data line, and a second auxiliary connection line electrically connected with the pad. The main connection line is provided with a first compensating portion at a position where the main connection line is connected with the first auxiliary connection line, and a second compensating portion at a position where the main connection line is connected with the second auxiliary connection line.

In a possible implementation, the array substrate further includes a plurality of dummy gate driver units disposed outside the display area and a plurality of dummy thin-film transistors electrically connected with output ends of the dummy gate driver units.

In a possible implementation, the array substrate further includes multiple first transistors in the display area. Along the second direction, a density of the dummy thin-film transistors is approximately equal to a density of the first transistors in the display area. Along the first direction, a density of dummy thin-film transistors in the bonding area is greater than a density of the first transistors in the display area.

Embodiments of the disclosure further provide a display panel, and the display panel includes the array substrate provided by the embodiments of the disclosure.

Embodiments of the disclosure further provide a display apparatus, and the display apparatus includes the display panel provided by the embodiments of the disclosure and a control chip, where the control chip is electrically connected with the pad groups via bonding.

### BRIEF DESCRIPTION OF FIGURES

FIG. 1 is a schematic diagram showing a block defect.

FIG. 2 is a conventional timing diagram for one pixel during a 1H charging period.

FIG. 3 is a schematic top view of an array substrate provided by embodiments of the disclosure.

FIG. 4 is a schematic enlarged view of a dashed box S1 shown in FIG. 3.

FIG. 5A is a schematic enlarged view of a dashed box Q1 shown in FIG. 4.

FIG. 5B is a schematic enlarged view of a dashed box Q2 shown in FIG. 5A.

FIG. 5C is a schematic enlarged view of a dashed box S2 shown in FIG. 4.

FIG. 5D is a schematic enlarged view of a dashed box S3 shown in FIG. 5C.

FIG. 5E is a schematic sectional view along a dashed line EF shown in FIG. 5C.

FIG. 6A is another schematic enlarged view of a dashed box S2 shown in FIG. 4.

FIG. 6B is a schematic sectional view along a dashed line EF shown in FIG. 6A.

FIG. 6C is a schematic enlarged view of one of junction lines in FIG. 6A.

FIG. 7 is a partial schematic diagram of a position where a connection line connects with the data line provided by embodiments of the disclosure.

FIG. 8 is a partial schematic diagram of a position where a connection line connects with a pad group provided by embodiments of the disclosure.

FIG. 9 is a schematic partially enlarged view of a dashed box S4 shown in FIG. 7.

FIG. 10 shows a range of resistance of a data line and the connection line connected with the data line shown in FIG. 9.

FIG. 11 shows a schematic enlarged view of a dashed box S6 shown in FIG. 7 and a schematic enlarged view of a dashed box S7 shown in FIG. 8.

FIG. 12 is a schematic diagram showing an arrangement of gate driver units in the related art.

FIG. 13 is a schematic diagram with dummy thin-film transistors provided by the embodiments of the disclosure.

### DETAILED DESCRIPTION

In order to make objectives, technical solutions and advantages of the embodiments of the disclosure clearer, the technical solutions of the embodiments of the disclosure are described clearly and completely below with reference to the drawings of the embodiments of the disclosure. Apparently, the described embodiments are some, not all, of the embodiments of the disclosure. Based on the described embodiments of the disclosure, all other embodiments obtained by those of ordinary skill in the art without inventive efforts fall within the protection scope of the disclosure.

Unless otherwise indicated, the technical or scientific terms used in the disclosure shall have the usual meanings understood by a person of ordinary skill in the art to which the disclosure belongs. The words “first”, “second” and the like used in the disclosure do not indicate any order, quantity or importance, but are only used to distinguish different components. The word “including” or “containing” and the like, means that an element or item preceding the word covers an element or item listed after the word and the equivalent thereof, without excluding other elements or items. The word “connection” or “coupling” and the like is not restricted to physical or mechanical connection, but may include electrical connection, whether direct or indirect. The terms “up”, “down”, “left”, “right”, etc., are used to indicate relative positional relationships, and when the absolute position of the described object changes, the relative positional relationship may change accordingly.

In the disclosure, “approximately” or “substantially the same” includes a stated value and is within an acceptable deviation range for specific values determined by a person skilled in the art considering the measurement and tolerance associated with measurement of specific parameters discussed (i.e., limitations of the measurement system). For example, “substantially the same” may mean that a difference from the stated value is within one or more standard deviation ranges or within +30%, 20%, 10%, or 5%.

In the drawings, to facilitate clear illustration, thickness of layers, films, panels, regions, etc., has been enlarged. Cross-sectional views based on schematic diagrams of idealized embodiments are used for illustrating exemplary embodiments. Thus, variations in shape that are anticipated as results of, for example, manufacturing technology and/or tolerances are foreseeable. Therefore, embodiments described herein should not be interpreted as limited to the specific shape of regions shown in the drawings but rather include deviations in shape resulting from, for example, manufacturing. For example, regions shown as flat may typically have rough and/or non-linear features. Additionally, sharp corners shown may be rounded. Thus, the regions shown in the drawings are illustrative in nature, and their shapes are not intended to represent the precise shape of regions, and they are not intended to limit the scope of the claims.

For clarity and conciseness of the following description of embodiments disclosed herein, detailed descriptions of known functions and known components are omitted.

Existing dual-gate display devices have multiple ICs (e.g., two ICs), causing a distance from a far end of the panel to the IC to increase. This leads to a significant difference in impedance between the far and near ends, resulting in black block (Block) defects or split-screen defects between ICs. Alternatively, to reduce a total length of the Printed Circuit Board (PCB), the leftmost and rightmost ICs on the edge of the panel are moved towards the center, which also resulting in the aforementioned block defects.

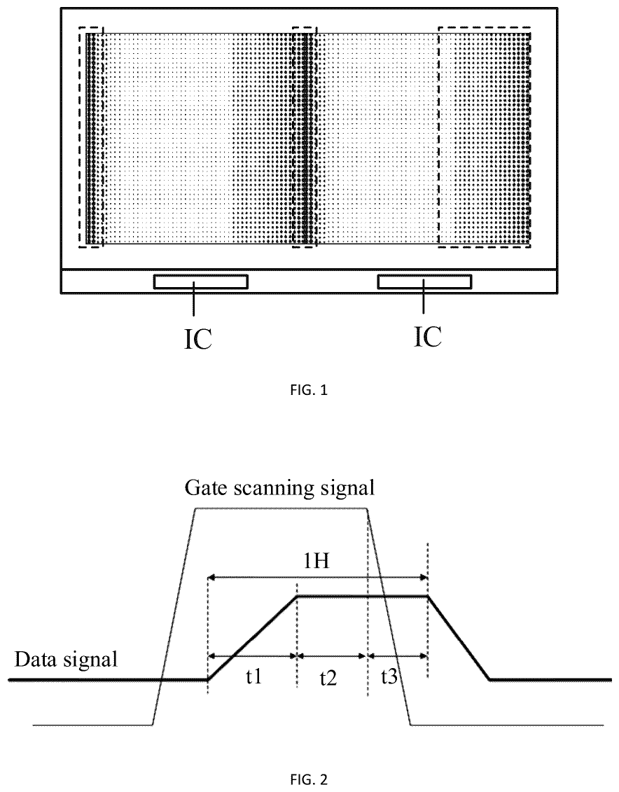

FIG. 1 illustrates a common block defect, where a position corresponding to the center of the IC is brighter, and the farther the panel end is from the IC, the darker it becomes. In this case, due to the long distance from the IC, obvious block or split-screen phenomena occur in the middle of the display area (AA) between the two ICs. The main reason is the impedance difference between the far and near ends of lines in the fan-out area, causing an imbalance in the load of data lines (Data) in the middle and on both sides of the IC. This results in significant differences in the charging rate of each pixel, leading to differences in brightness of each pixel, and ultimately manifesting as block defects. Specifically, FIG. 2 is a conventional timing diagram for one pixel during the 1H charging period, where t1 is a delay time of a data line, mainly related to the impedance and capacitance of the panel load; t2 is the effective charging time, and t3 is the time from when the gate signal begins to be turned off until the data signal is turned off. It can be seen that the larger the value of t1, the shorter the effective charging time of t2, resulting in a smaller pixel charging rate. Therefore, t1 is an important parameter that must be strictly controlled. The delay time of the data line satisfies a following relationship:

t1=R*C.

Here R indicates a resistance value on the data line, and C indicates a capacitance of each data line.

As can be seen from the above formula, since the number of pixels in each column is consistent, the capacitance C of each data line in the display area can be considered consistent, and there is no facing overlap capacitance due to an alternative wiring design at a bottom of panel, so that the capacitance of each data line can be considered consistent. Due to the consistent number of columns of pixels in the display area, the resistance value R on each data line can be considered to be consistent. Therefore, a difference in the resistance value R on each data line mainly manifests in the fan-out wiring area. Due to the current demand for low cost, narrow bezels, and narrow PCB boards, reducing the number of ICs by half can halve the cost of ICs, resulting in a longer wiring distance and a larger difference in impedance between the far and near ends. The narrower the bezel, the smaller the fan-out wiring space, the finer the line, and the larger the difference in impedance between the far and near ends. The shorter the length of the PCB board, the closer the placement of the IC to the center of the panel, and also the larger the difference in impedance between the far and near ends. Therefore, there is an urgent need to innovate the design of the existing Fan-out wiring area, optimize the design method, and solve the problem of display defects.

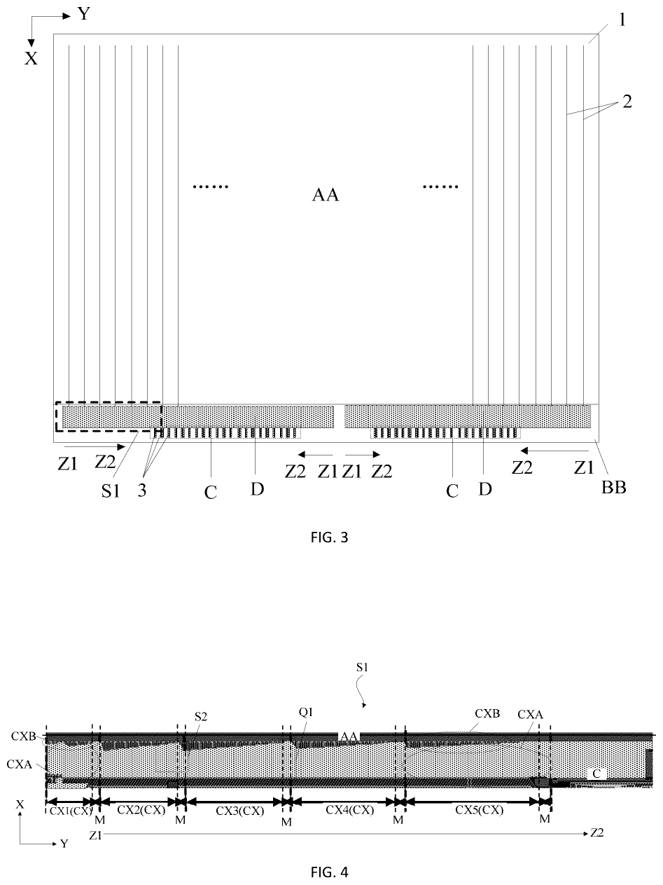

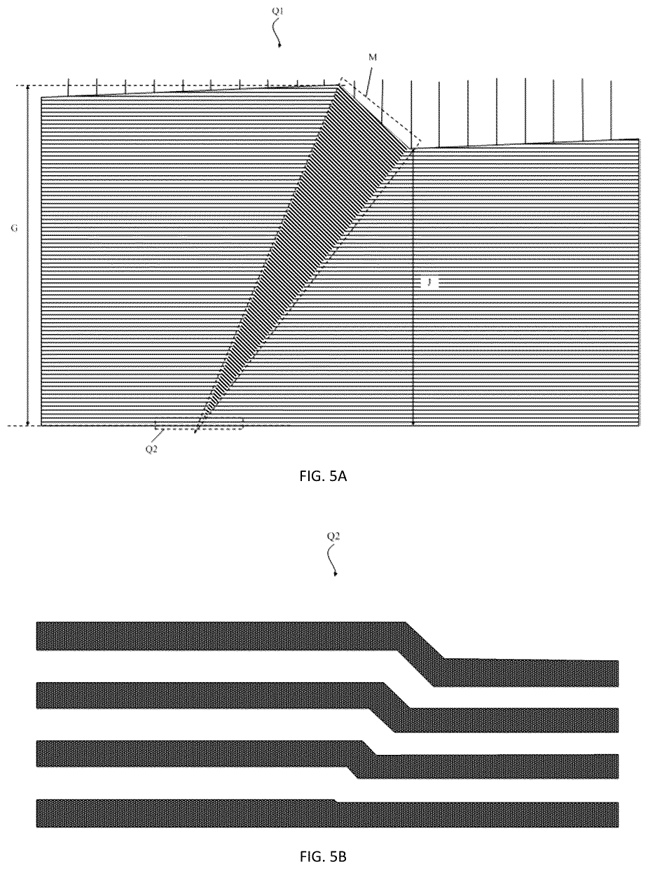

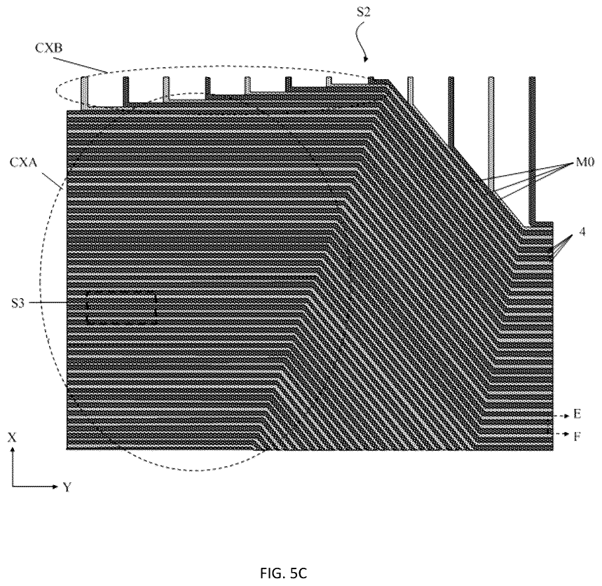

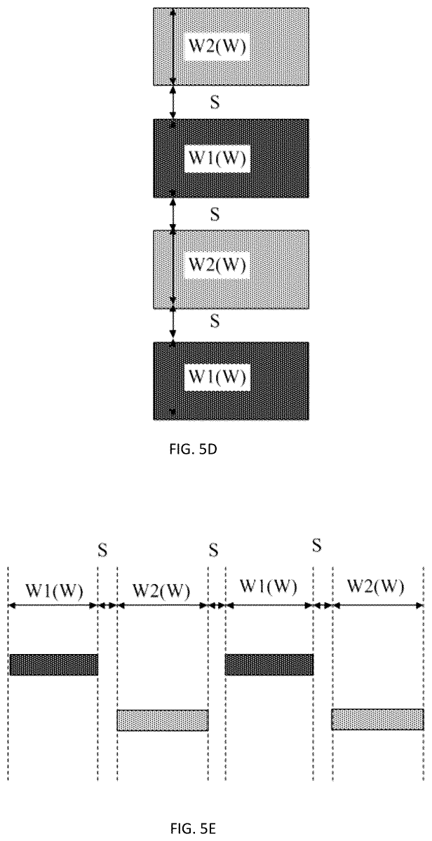

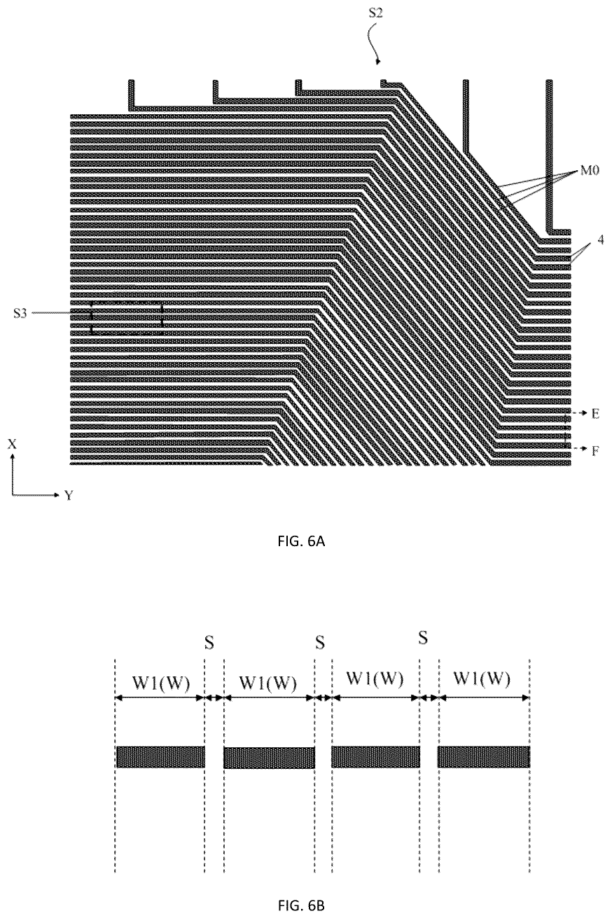

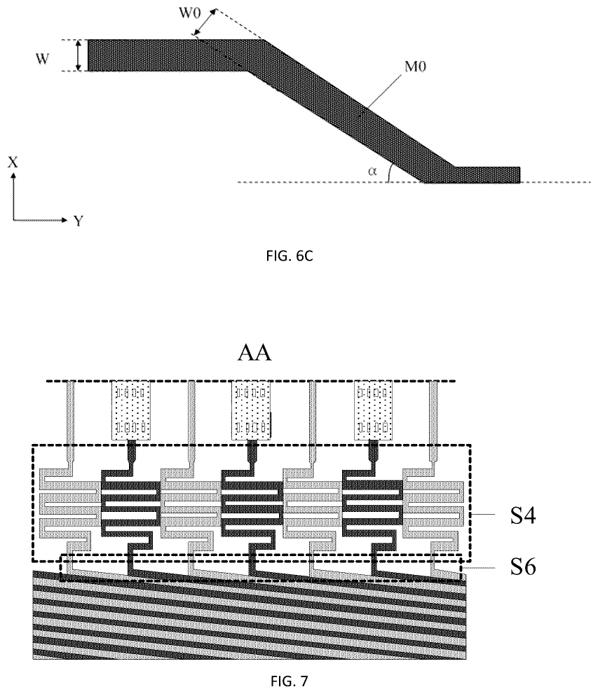

In view of the issue, embodiments of the disclosure provide an array substrate, as shown in FIGS. 3, 4, 5A-5E, 6A-6C. FIG. 4 is a schematic enlarged view of a dashed box S1 shown in FIG. 3. FIG. 5A is a schematic enlarged view of a dashed box Q1 shown in FIG. 4. FIG. 5B is a schematic enlarged view of a dashed box Q2 shown in FIG. 5A. FIG. 5C is a schematic enlarged view of a dashed box S2 shown in FIG. 4. FIG. 5D is a schematic enlarged view of a dashed box S3 shown in FIG. 5C. FIG. 5E is a schematic sectional view along a dashed line EF shown in FIG. 5C. FIG. 6A is another schematic enlarged view of a dashed box S2 shown in FIG. 4. FIG. 6B is a schematic sectional view along a dashed line EF shown in FIG. 6A. FIG. 6C is a schematic enlarged view of one of junction lines in FIG. 6A. The array substrate has a display area AA, and a boding area BB on a side of the display area AA. The array substrate includes:
a substrate 1;
a plurality of data lines 2, disposed on a side of the substrate 1 in the display area AA, and extending along a first direction X;
at least one pad group C, disposed on a same side of the substrate 1 as the data lines 2 in the bonding area BB; where the at least one pad group C includes a plurality of pads 3 arranged along a second direction Y; specifically, the pads of pad group C of the array substrate can be subsequently correspondingly bonded to pads of the control chip IC in a one-to-one correspondence;
at least one connection line group D, disposed on the same side of the substrate 1 as the data lines 2 in the bonding area BB; where the connection line group D includes a plurality of connection lines 4, one end of each connection line 4 is electrically connected with a data line 2, and the other end of each connection line is electrically connected with a pad 3; and within a same connection line group D, the connection lines 4 are all electrically connected with a same pad group C; specifically, the connection lines 4 electrically connected with one pad group C can be taken as one connection line group D.

In the connection line group D, multiple connection lines 4 located on at least one side of the pad group C are arranged in multiple wiring regions CX along a second direction Y; the connection lines 4 in the same wiring region CX have approximately equal line widths (W); further, in a direction from a connection line 4 at an outermost edge of the connection line group D to the pad group C (as indicated by the arrow from Z1 to Z2 in FIG. 3 or FIG. 4), the line widths (W) of the connection lines 4 in the wiring regions CX decrease. Specifically, the line widths (W) of the connection lines 4 in the wiring regions CX may decrease gradually. For example, as shown in FIG. 4, the region between the display area AA and the pad group C can be divided, in the direction from the connection line 4 at the outermost edge of the connection line group D to the pad group C, into a first wiring region CX1, a second wiring region CX2, a third wiring region CX3, a fourth wiring region CX4, and a fifth wiring region CX5. In this case, a line width of the connection lines 4 in the first wiring region CX1 is greater than a line width of the connection lines 4 in the second wiring region CX2; the line width of the connection lines 4 in the second wiring region CX2 is greater than a line width of the connection lines 4 in the third wiring region CX3, the line width of the connection lines 4 in the third wiring region CX3 is greater than a line width of the connection lines 4 in the fourth wiring region CX4, and the line width of the connection lines 4 in the fourth wiring region CX4 is greater than a line width of the connection lines 4 in the fifth wiring region CX5.

In the embodiments of the disclosure, the connection lines 4 between the display area AA and the pad group C are divided into several wiring regions CX. The connection lines 4 in the same wiring region CX have approximately equal line widths (W), and in the direction from the connection line 4 at the outermost edge of the connection line group D to the pad group C, the line widths (W) of the connection lines 4 in the wiring regions CX decrease gradually. This means increasing the line width of the connection lines 4 at the far end, thus reducing the resistance of the connection lines 4 at the far end, and narrowing the resistance difference between the connection lines 4 at the far end and the connection lines 4 at the near end. This allows the resistance of the connection lines 4 at the respective positions to be substantially same, and helps mitigate block display defects or split-screen defects.

It should be noted that when there is just one pad group C on the display panel, the direction from the connection line 4 at the outermost edge of the connection line group D to the pad group C may be a direction from the outermost edge of the display panel to the pad group C. For display panels provided with two pad groups C, the direction from the connection line 4 at the outermost edge of the connection line group D to the pad group C may be a direction from the middle of the display panel towards the pad group C.

In a possible implementation, line spacings(S) between the connection lines 4 in the wiring regions CX decrease in the direction from the connection line 4 at the outermost edge of the connection line group D to the pad group C. Specifically, in the direction from the connection line 4 at the outermost edge of the connection line group D to the pad group C, the line spacings(S) between the connection lines 4 in the wiring regions CX may decrease gradually.

In the embodiments of the disclosure, as a distance from the pad group C increases, the quantity of connection lines 4 decreases, the wiring space along the first direction X increases, and the line width (W) and line spacing(S) of the connection lines 4 can be designed to be larger. As the distance from the pad group C decreases, the quantity of connection lines 4 increases, the wiring space along the first direction X decreases, and the line width (W) and line spacing(S) of the connection lines 4 need to be designed smaller. By making the line widths (W) of the connection lines 4 in the wiring regions CX decrease gradually and the line spacing(S) of the connection lines 4 in the wiring regions CX decrease gradually in the direction from the connection line 4 at the outermost edge of the connection line group D to the pad group C, the space for each wiring region CX can be effectively utilized. This increases the line width (W) of the connection lines 4 at the far end, reduces the resistance of the connection lines 4 at the far end, narrows the resistance difference between the connection lines 4 at the far end and the connection lines 4 at the near end, and thereby improving black block (Block) display defects or split-screen defects.

In a possible implementation, as shown in FIGS. 5C-5E, the connection lines 4 can be alternately wired using a double-layer metal. For example, a gate line layer (Gate) and a data line layer (SD) are arranged alternately. In another possible implementation, as shown in FIGS. 6A-6C, the connection lines 4 can use a single-layer metal wiring layout. For example, either a gate line layer (Gate) or a data line layer (SD) is used for layout.

It should be noted that FIG. 4 schematically illustrates the division of the area between the left edge and the left pad group C in the area between the display area AA and the pad group C into five wiring regions CX. In actual implementation, the area between the display area AA and the pad group C can be set to other numbers of wiring regions CX, such as 4 wiring regions CX, 5 wiring regions CX, 6 wiring regions CX, 7 wiring regions CX, 8 wiring regions CX, 9 wiring regions CX, or 10 wiring regions CX.

In a possible implementation, combining FIGS. 5C-5E and 6A-6C, a line width (W) of one connection line 4 and a line spacing(S) between two adjacent connection lines in a wiring region CX satisfy a following relationship:

$$W = \frac{2 fn ( G + S )}{3 km} - S ;$$

here, k indicates a sequential index of a wiring region CX in the direction from the edge of the connection line group D to the pad group C (i.e., corresponding to the which one of wiring regions, for example, in FIG. 4, the sequential index of the leftmost wiring region CX1 can be 1, and the sequential index of the rightmost wiring region CX5 can be 5), which can be a constant from 1 to 10; f indicates the quantity of wiring regions CX in the direction from the edge of the connection line group D to the pad group C and can be a constant from 4 to 10; m indicates a display resolution along the second direction Y of the array substrate; n indicates the quantity of pad groups C; G indicates the maximum width of the wiring region in the first direction X, which is a distance in the first direction X from a connection line 4 closest to array substrate to a connection line 4 farthest to a bottom edge of the array substrate (the bottom edge may be an edge of the array substrate closest to the pad group C in the first direction X).

Specifically, the display resolution along the second direction Y of the array substrate can be the resolution in units of pixel units, where a pixel unit includes three sub-pixels: red, green, and blue. If m indicates the display resolution along the second direction Y, then the quantity of data lines 2 may be 3 m.

In a possible implementation, combining FIGS. 5C-5E and 6A-6C, the line width (W) of the connection line 4 and the line spacing(S) between the two adjacent connection lines may further satisfy a following relationship:

$$15 \% \leq \frac{S}{W + S} \leq 50 \% .$$

In this way, during a process of manufacturing the display panel, when the sealant between the array substrate and the opposite substrate is UV-cured, the relationship between the line width (W) and line spacing(S) can meet the transmittance requirements for curing the sealant. This avoids the situation where the line width (W) or line spacing(S) is too large or too small to affect the curing effect of the sealant.

In a possible implementation, a line width (W) difference of the connection lines 4 between any two adjacent wiring regions CX is equal. Specifically, for example, a difference in line width of the connection lines 4 between the first wiring region CX1 and the second wiring region CX2 may be 0.5 μm, and a difference in line width of the connection lines 4 between the third wiring region CX3 and the fourth wiring region CX4 may also be 0.5 μm.

In a possible implementation, a difference in line width (W) of connection lines 4 of any two adjacent wiring regions CX is greater than or equal to 0.5 μm.

Specifically, for example, the line widths (W) of the connection lines 4 in the first wiring region CX1 can be 4.0 μm to 10 μm, the line widths (W) of the connection lines 4 in the second wiring region CX2 can be 3.5 μm to 8.0 μm, the line widths (W) of the connection lines 4 in the third wiring region CX3 can be 3.0 μm to 5.5 μm, the line widths (W) of the connection lines 4 in the fourth wiring region CX4 can be 2.5 μm to 4.5 μm, and the line widths (W) of the connection lines 4 in the fifth wiring region CX5 can be 2.0 μm to 4 μm.

In a possible implementation, in the direction from the connection line 4 at the outermost edge of the connection line group D to the pad group C, the quantity of connection lines 4 in the wiring regions CX are equal or increase.

In a possible implementation, on the second direction Y, the quantity H of connection lines 4 at the wiring region CX furthest from the pad group C can satisfy a following relationship:

$$H = \frac{3 m}{2 n \times f} .$$

Here, f indicates the quantity of wiring regions CX in the direction from the edge of the connection line group D to the pad group C, m indicates the display resolution along the second direction Y of the array substrate, and n indicates the quantity of pad groups C.

In a possible implementation, in the direction from the connection line 4 at the outermost edge of the connection line group D to the pad group C, the quantity of connection lines 4 in adjacent wiring regions CX is increased by H in turn. Specifically, H can typically be designed as 60 to 200.

In a possible implementation, as shown in FIG. 4, lengths of the wiring regions CX on the second direction Y increase in the direction from the connection line 4 at the outermost edge of the connection line group D to the pad group C. Specifically, the lengths of the wiring regions CX on the second direction Y can increase gradually in the direction from the connection line 4 at the outermost edge of the connection line group D to the pad group C.

Specifically, in a direction from the connection line 4 the outermost edge of the connection line group D to the pad group C, the length d of each wiring region CX on the second direction Y can satisfy a following relationship:

d=H*P.

Here, P indicates a width of a sub-pixel on the array substrate along the second direction Y. Specifically, the range of lengths (d) of the wiring regions CX on the second direction Y can be designed as 5 mm to 20 mm.

In a possible implementation, as shown in FIGS. 4 and 5C, the wiring region CX includes: a first sub-wiring region CXA and a second sub-wiring region CXB located on a side of the first sub-wiring region CXA facing the display area AA. The connection lines 4 extend along the first direction X in the second sub-wiring region CXB. In the direction from the connection line 4 at the outermost edge of the connection line group D to the pad group C, a ratio of a second sub-wiring region CXB to a wiring region CX including the second sub-wiring region CXB gradually decreases. For example, as shown in FIG. 4, connection lines 4 extending along the first direction X are distributed in the entire first wiring region CX1 on the leftmost. In the first wiring region CX1, a ratio of the second sub-wiring region CXB to the entire first wiring region CX1 can be 100%. However, for the fifth wiring region CX5 on the right side, just a portion of the region has connection lines 4 extending along the first direction X. In the fifth wiring region CX5, a ratio of the second sub-wiring region CXB to the entire fifth wiring region CX5 can be, for example, 80%.

In a possible implementation, a resistance (R_{fmax}) of the connection line 4 at the outermost edge satisfies a following relationship:

$${R}_{fmax} \leq \frac{7 \times {R}_{aa}}{13} + \frac{20 \times {R}_{fmin}}{13} .$$

Here, Rₐₐ indicates a resistance of the data line 2, R_{fmin} indicates a resistance of the connection line 4 extending along the first direction X between the pad group C and the display area AA. This ensures that a resistance difference between the connection line 4 at the far end and the connection line 4 at the near end is smaller than or equal to 35%. Consequently, when displaying images, a difference in grayscale can be less than a recognizable difference in grayscale by the human eye (typically the human eye can recognize a difference in grayscale of two levels, approximately 1 grayscale≈12 mV, i.e., a case of voltage difference of 24 mV is visible).

Specifically, a percentage of the difference (ΔR) in resistance between the connection line at the far end and the connection line at the near end may satisfy a following relationship:

$$Δ R = \frac{{R}_{max} - {R}_{min}}{{R}_{max}} \times 100 \% , R = {R}_{aa} + {R}_{fanout} .$$

Here, Rₘₐₓ indicates a resistance value of the connection line 4 at the far end of the panel (corresponding to the connection line 4 near “Z1” in FIG. 4), and Rₘᵢₙ indicates a resistance value of the connection line 4 at the position directly above the pad group C. Here, Rₐₐ indicates the resistance value of the data line on the panel in the display area (the resistance value on each data line is usually the same), and R_{fanout} indicates a resistance value of the connection line between the display area and the pad group C (requiring control design). The table below shows the simulation values of charging voltage for different image corresponding to the resistance difference of a certain display product.

| Item | Image of grayscale G127 | | | Image of grayscale G255 | | | |
|---|---|---|---|---|---|---|---|
| ΔR | Vmin | Vmax | ΔV | Vmin | Vmax | ΔV | Effect |
| 38% | 9.2049 | 9.2215 | 16.6 | 10.619 | 10.647 | 28 mV | Block is visible |
| 35% | 9.312 | 9.327 | 15 | 10.846 | 10.869 | 23 mV | NO Block |
| 30% | 9.3984 | 9.4116 | 13.2 | 11.028 | 11.047 | 19 mV | NO Block |

From the above table, it can be seen that when designing the wiring between the panel display area and the pad group C, the impedance difference AR between the near and far ends should be smaller than or equal to 35% to prevent block defects.

In a possible implementation, as shown in FIGS. 5C-5E and 6A-6C, the array substrate further includes a junction region M between adjacent wiring regions CX. The junction region M includes junction lines M0 electrically connected one by one with at least part of the connection lines 4 in the adjacent wiring regions CX, and an extension direction of the junction lines M0 intersect with the extension direction of the connection lines 4. Specifically, as shown in FIGS. 5A and 5B, some connection lines 4 may enter the adjacent wiring region CX without the junction lines M0. For example, in FIG. 5B, the bottommost connection line 4 may enter the adjacent wiring region CX just after a change in width without bending.

In a possible implementation, as shown in FIGS. 5C-5E and 6A-6C, in a same junction line M0, a minimum distance from the end closer to the pad group C to the display area AA is greater than a minimum distance from the end farther from the pad group C to the display area AA. In other words, the junction line M0 is formed as an inclined line, and a lower end thereof is closer to the pad group C.

Specifically, as shown in FIG. 6C, an included angle α between the junction line M0 and the second direction Y, on the side far from the pad group C, ranges from 30° to 65°. For example, it can be 30°, 35°, 40°, 45°, 50°, 55°, 60°, or 65°.

Specifically, as shown in FIG. 6C, the line width W0 of the junction line M0 can be the same as the line width W0 of the connection line 4 in the adjacent wiring region CX on the side away from the pad group C. The line spacing S of the junction lines M0 can be the same as the line spacing S of the connection lines 4 in the adjacent wiring region CX on the side away from the pad group C.

In a possible implementation, as shown in FIG. 5A, in the direction from the connection line 4 at the outermost edge of the connection line group D to the pad group C, minimum widths J of at least two adjacent wiring regions CX in the first direction X increase. For example, in FIG. 4, a minimum width J of the second wiring region CX2 in the first direction X is greater than a minimum width J of the first wiring region CX1 in the first direction X. For another example, a minimum width J of the third wiring region CX3 in the first direction X is greater than the minimum width J of the second wiring region CX2 in the first direction X.

It should be noted that, since new connection line(s) 4 is/are added to each wiring region CX on the side facing the display area AA, the minimum width J of the wiring region CX in the first direction X can be a width on the side of the wiring region CX adjacent to a previous junction region M (the previous junction region M is the junction region adjacent to the wiring region CX and on the side away from the pad group C), as shown in FIG. 5A. That is, the minimum width J of the wiring region CX in the first direction X is a distance value in the first direction X between a new connection line 4 added to the wiring region CX and a connection line 4 closest to the bottom edge of the display panel (i.e., the connection line 4 at the bottommost in FIG. 5A).

It can be understood that, as shown in FIG. 5A, the quantity of connection lines 4 in the wiring region CX includes the quantity of connection lines 4 added in the junction region M adjacent to the wiring region CX and located at a side of the wiring region CX away from the pad group C. For example, in FIG. 5A, the quantity of connection lines 4 of the wiring region CX on the right side also includes the quantity of the two connecting wires 4 newly added to the junction region M on its left side.

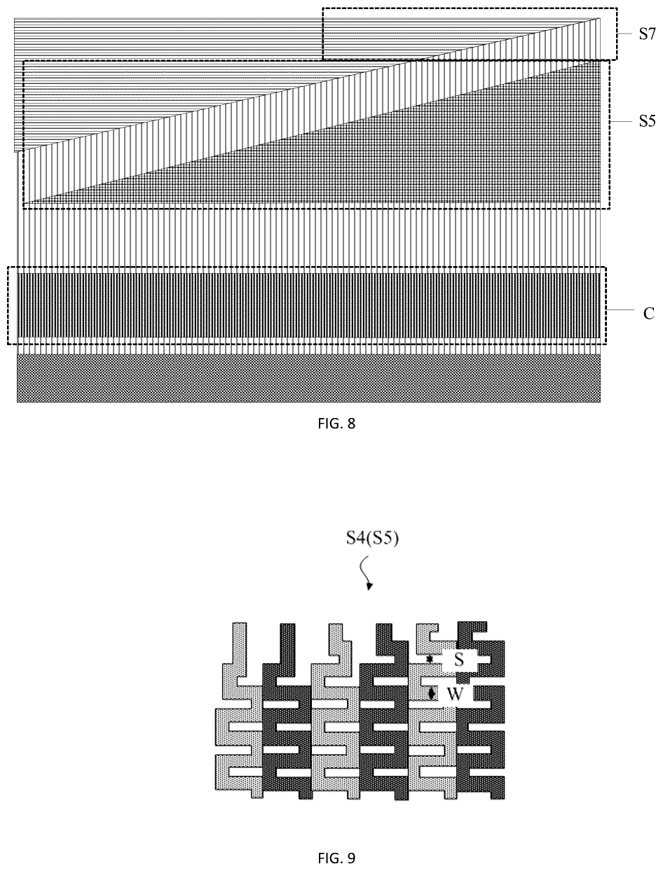

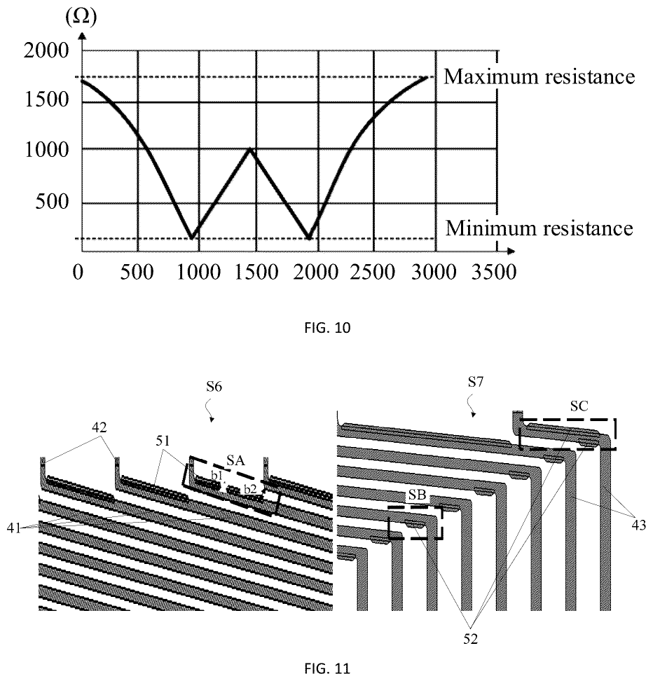

In a possible implementation, as shown in FIGS. 7, 8, 9, and 10, where FIG. 9 can be a schematic partially enlarged view of a dashed box S4 shown in FIG. 7 or of a dashed box S5 shown in FIG. 8. FIG. 10 shows a range of resistance of a data line and the connection line connected with the data line shown in FIG. 9. The abscissa of FIG. 10 indicates sequential index of the data line and the connection line connected with the data line, and the ordinate indicates the resistance of the data line and the connection line connected with the data line. In FIG. 7, a shape of the connection line 4 in at least part of the position where the connection line is electrically connected with the data line 2 is bent, and in FIG. 8, a shape of the connection line 4 in at least part of the position where the connection line is electrically connected with the pad group C is bent. In the embodiments of the disclosure, the shape of the connection line 4 in at least part of the position where the connection line is electrically connected with the data line 2 is bent, and/or, the shape of the connection line 4 in at least part of the position where the connection line is electrically connected to the pad group C is bent, so that the resistance difference between adjacent two connection lines 4 can be effectively reduced, to allow the resistance of the line to change uniformly without abrupt variations. Specifically, the difference (ΔR) in resistance between adjacent two connection lines 4 is smaller than or equal to 1%, so display defects can be prevented.

In a possible implementation, the shape of the connection line 4 at the position where the connection line is electrically connected with the data line 2 includes an S-shape, a shape like Chinese character “ [symbol] ”, or a folded line shape. The shape like Chinese character “ [symbol] ” means that the connection line 4 at the position where the connection line is electrically connected with the data line 2 may include a plurality of first portions and a plurality of second portions, the plurality of first portions and the plurality of second portions are alternately connected with each other, and an extension direction of the first portion is different from that of the second portion, that is, for a second portion, an end of the second portion is connected with one first portion, and the other end of the second portion is connected with another first portion, and each first portion may be perpendicular to each second portion.

Specifically, for the connection lines 4 in the region shaped like the Chinese character “ [symbol] ”, a line width W can be 2.0 μm to 8.0 μm, and a line spacing S can be 4.0 μm to 10.0 μm, that is, a line spacing between two second portions of the connection line 4 at the position where the connection line is electrically connected with the data line 2 can be 4.0 μm to 10.0 μm, as shown in FIG. 9.

In a possible implementation, as shown in FIG. 11, where the left part of FIG. 11 may be a schematic enlarged view of the dashed box S6 in FIG. 7, and the right part of FIG. 11 may be a schematic enlarged view of the dashed box S7 in FIG. 8. The connection line 4 includes a main connection line 40, a first auxiliary connection line 41 electrically connected with the data line 2, and a second auxiliary connection line 42 electrically connected with the pad 3. At the position where the main connection line 40 is connected with the first auxiliary connection line 41 (such as the dashed box SA), the main connection line 40 is provided with a first compensating portion 51. At the position where the main connection line 40 is connected with the second auxiliary connection line 42 (such as the dashed box SB), the main connection line 40 is provided with a second compensating portion 52. In the embodiments of disclosure, adding the first compensating portion 51 at the position where the main connection line 40 is connected with the first auxiliary connection line 41 and adding the second compensating portion 52 at the position where the main connection line 40 is connected with the second auxiliary connection line 42, can prevent a situation that: during a patterning process for the connection lines, the areas surrounding the connection lines 4 in the regions where the dashed boxes SA, SB and SC are located correspond to light transmitting areas for exposure in the mask, if a line width of a metal line is designed to be small (for example, smaller than or equal to 4 μm), a large amount of exposure to these areas may cause the line width in the region where the dashed boxes SA, SB and SC are located to become very fine, leading to possible line break defects.

Specifically, the first compensating portion 51 may be located at the side of the main connection line 40 facing the display area AA, and the second compensating portion 52 may be located at the side of the main connection line 40 facing the pad group C. Specifically, for connection lines 4 inside the wiring region CX, the first compensating portion 51 or the second compensating portion 52 may be provided at one side of the connection line 4 (such as the dashed boxes SA, SB in FIG. 11). For connection lines 4 at the edge of the wiring region CX, the first compensating portion 51 or the second compensating portion 52 can be provided on both sides of the connection line 4 (such as the dashed box SC in FIG. 11).

Specifically, in the regions where the dashed boxes SA, SB and SC are located, a line width b1 of the added first compensating portion 51 (or second compensating portion 52) may be in a range of 0.7 μm to 1.5 μm. A distance b2 between the line provided with the first compensating portion 51 (or second compensating portion 52) and the corner may be in a range of 3.0 μm to 7 μm.

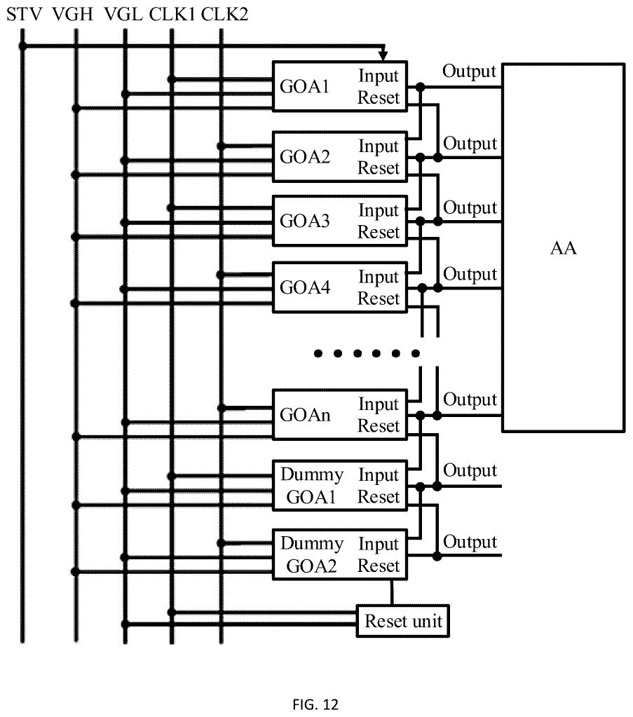

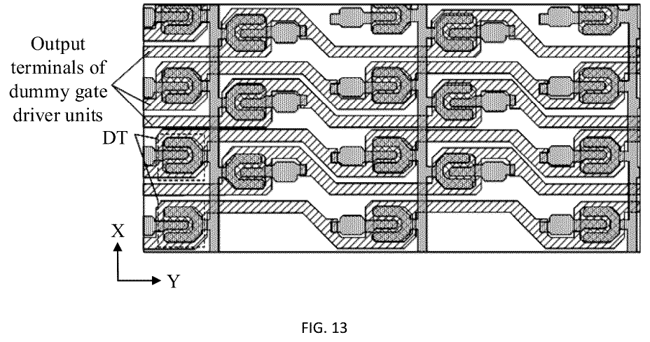

In the related art, as shown in FIG. 12, it can be seen that the output terminal (Output) of the gate driver unit GOA in a row connects both a reset terminal (Reset) of a previous gate driver unit GOA and an input terminal (Input) of a subsequent gate driver unit GOA, thus their waveforms influence each other. To reset the last gate driver unit GOA (n), a dummy gate driver unit GOA (DG) is designed, but the dummy gate driver unit GOA is not connected to the display area (Active Area, AA), i.e., it does not connected with a load of the AA. However, because there is no display area pixel unit to which the dummy gate driver unit GOA can be connected, it leads to inconsistency in the load between the rows of dummy gate driver units GOA and the gate driver units GOA in the normal area.

In view of this, as shown in FIG. 13, the array substrate in the embodiments of the disclosure includes multiple dummy gate driver units DG located outside the display area AA, and further includes multiple dummy thin-film transistors (Dummy TFT, DT) electrically connected with output terminals (Output) of the dummy gate driver units DG. In the embodiments of the disclosure, the array substrate further includes multiple dummy thin-film transistors DT electrically connected with the output terminals (Output) of the dummy gate driver units DG, so that the load on the output terminal (Output) of the dummy gate driver unit DG can be made substantially consistent with the load on the output terminal (Output) of the normal gate driver unit GOA. Moreover, the design of the dummy thin-film transistors DT without setting pixels, can significantly reduce the space of the display panel on the first direction X, thereby reducing the bottom border of the display panel. By adding the dummy thin-film transistors DT, it ensures that a density of the gate patterns, source-drain patterns, and active layer patterns outside the display area AA is consistent with that within the display area. This makes the film uniform around the display area, especially for oxide thin-film transistor display panel products, effectively improving the problem of uneven conduction caused by uneven source-drain patterns around the display area. Furthermore, the addition of the dummy thin-film transistors DT can effectively prevent static electricity in the pad group C and other positions from entering into the display area to burn out the transistors, causing short circuits between power lines and data lines (i.e., DGS defects) or short circuits between source and drain electrodes. In embodiments of the disclosure, the static electricity is first conducted to the dummy thin-film transistors DT and causes short circuits between the source and drain electrodes in the dummy thin-film transistors DT without actually affecting the display.

In a possible implementation, the array substrate further includes a plurality of first transistors T1 in the display area AA. In the second direction, a density of the dummy thin-film transistors DT is approximately equal to a density of the first transistors T1 in the display area AA, which can ensure that the load on the output terminal (Output) of the dummy gate driver unit DG is substantially the same as the load on the output terminal (Output) of the normal gate driver unit GOA. In the first direction X, a density of the dummy thin-film transistors DT in the bonding area BB is greater than a density of the first transistors T1 in the display area AA. This effectively reduces the space of the display panel on the first direction X, thereby reducing the bottom border of the display panel.

Specifically, a size of the dummy thin-film transistors DT for the output terminal of the dummy gate driver unit DG is designed to be consistent with a size of the transistors in the display area (i.e., a shape and size of the source-drain pattern of the dummy thin-film transistors DT is consistent with a shape and size of the source-drain pattern of the transistors in the display area, a shape and size of the gate pattern of the dummy thin-film transistors DT is consistent with a shape and size of the gate pattern of the transistors in the display area, and a shape and size of the active layer pattern of the dummy thin-film transistors DT is consistent with a shape and size of the active layer pattern of the transistors in the display area).

Specifically, the quantity of dummy thin-film transistors DT connected with the output terminal of the dummy gate driver unit DG is the same as the quantity of transistors connected with the output terminal of the gate driver unit GOA in the display area.

Specifically, a spacing between two adjacent gate lines (upper and lower) connected to with output terminal of the dummy gate driver unit DG can be 5 μm to 10 μm, which can be smaller than a spacing between two adjacent gate lines in the display area.

Based on the same inventive conception, embodiments of the disclosure further provide a display panel, including the array substrate provided by the embodiments of the disclosure.

Based on the same inventive conception, embodiments of the disclosure further provide a display apparatus, including the display panel provided by the embodiments of the disclosure, and further including a control chip IC, where the control chip IC is electrically connected with the pad group C.

Although the preferred embodiments of the disclosure have been described, those skilled in the art will be able to make additional changes and modifications to these embodiments once the basic inventive concepts are apparent. Therefore, it is intended that the appended claims be construed to include the preferred embodiments and all changes and modifications that fall within the scope of this disclosure.

Obviously, those skilled in the art can make various changes and modifications to the disclosed embodiments without departing from the spirit and scope of the disclosed embodiments. In this way, if these modifications and variations of the embodiments of the disclosure fall within the scope of the claims of the disclosure and equivalent technologies, the disclosure is also intended to include these modifications and variations.

What is claimed is:

1. An array substrate comprising a display area and a bonding area on a side of the display area, wherein the array substrate comprises:
a substrate;
a plurality of data lines disposed on a side of the substrate in the display area and extending along a first direction;
at least one pad group disposed on a same side of the substrate as the plurality of data lines in the bonding area; wherein the pad group comprises a plurality of pads arranged sequentially along a second direction;
at least one connection line group disposed on the same side of the substrate as the plurality of data lines in the bonding area; wherein the connection line group comprises a plurality of connection lines, an end of a connection line is electrically connected with a data line, and other end of the connection line is electrically connected with a pad, and connection lines of a same connection line group are electrically connected with a same pad group;
wherein,
in the connection line group, multiple connection lines located on at least one side of the pad group are arranged in multiple wiring regions along the second direction;
in a same wiring region, a line width of each connection line is approximately equal; and
in a direction from a connection line at an outermost edge of the connection line group to the pad group, line widths of connection lines in the multiple wiring regions decrease.

2. The array substrate according to claim 1, wherein, in the direction from the connection line at the outermost edge of the connection line group to the pad group, line spacings between the connection lines in the multiple wiring regions decrease.

3. The array substrate according to claim 1, wherein a line width indicated as W of one connection line and a line spacing indicated as S between two adjacent connection line in each wiring region satisfy a following relationship:
$$W = \frac{2 fn ( G + S )}{3 km} - S ;$$
wherein k indicates a sequential index of the wiring regions in a direction from an edge of the connection line group to the pad group, f indicates a quantity of wiring regions in the direction from the edge of the connection line group to the pad group, m indicates a display resolution along the second direction of the array substrate, n indicates a quantity of pad groups, and G indicates a maximum width of the wiring region along the first direction.

4. The array substrate according to claim 3, wherein the line width indicated as W of the connection line and the line spacing indicated as S between the two adjacent connection lines further satisfy a following relationship:
$$15 \% \leq \frac{S}{W + S} \leq 50 \% .$$

5. The array substrate according to claim 1, wherein a line width difference between connection lines of any two adjacent wiring regions is equal.

6. The array substrate according to claim 1, wherein in the direction from the connection line at the outermost edge of the connection line group to the pad group, a quantity of connection lines in the multiple wiring regions increase; and
wherein in the direction from the connection line at the outermost edge of the connection line group to the pad group, lengths of the multiple wiring regions on the second direction are equal or increase.

7. The array substrate according to claim 6, wherein, along the second direction, a quantity indicated as H of connection lines in a wiring region farthest from the pad group satisfies a following relationship:
$$H = \frac{3 m}{2 n \times f} ;$$
wherein f indicates a quantity of wiring regions in the direction from the edge of the connection line group to the pad group, m indicates a display resolution along the second direction of the array substrate, and n indicates a quantity of pad groups.

8. The array substrate according to claim 7, wherein, in the direction from the connection line at the outermost edge of the connection line group to the pad group, a quantity of connection lines in adjacent wiring regions is increased by H in turn.

9. The array substrate according to claim 7, wherein, in the direction from the connection line at the outermost edge of the connection line group to the pad group, a length indicated as d of each wiring region along the second direction satisfies a following relationship:
d=H*P;
wherein P indicates a width of a sub-pixel on the array substrate in the second direction.

10. The array substrate according to claim 1, wherein the wiring region comprises a first sub-wiring region and a second sub-wiring region located on a side of the first sub-wiring region facing the display area, and connection lines in the second sub-wiring region extend along the first direction;
in the direction from the connection line at the outermost edge of the connection line group to the pad group, a ratio of a second sub-wiring region to a wiring region comprising the second sub-wiring region gradually decrease.

11. The array substrate according to claim 1, wherein a line resistance indicated as R_{fmax} of the connection line at the outermost edge satisfies a following relationship:
$${R}_{fmax} \leq \frac{7 \times {R}_{aa}}{13} + \frac{20 \times {R}_{fmin}}{13} ;$$
wherein Rₐₐ indicates a resistance of the data line, and R_{fmin} indicates a resistance of a connection line extending along the first direction between the pad group and the display area.

12. The array substrate according to claim 1, further comprising a junction region between adjacent wiring regions, wherein the junction region comprises junction lines electrically connected one-to-one with at least part of connection lines in the adjacent wiring regions, and an extension direction of the junction lines intersect with an extension direction of the connection lines.

13. The array substrate according to claim 12, wherein an included angle indicated as a formed between the junction line and the second direction ranges from 30° to 65°.

14. The array substrate according to claim 12, wherein a line width of the junction lines is the same as a line width of connection lines in an adjacent wiring region on a side away from the pad group; and
a line spacing of the junction lines is the same as a line spacing of the connection lines in the adjacent wiring region on the side away from the pad group.

15. The array substrate according to claim 1, wherein, in the direction from the connection line at the outermost edge of the connection line group to the pad group, minimum widths of at least two adjacent wiring regions in the first direction increase.

16. The array substrate according to claim 1, wherein a shape of the connection line in at least part of a position where the connection line is electrically connected with the data line is bent; a shape of the connection line in at least part of a position where the connection line is electrically connected with the pad group is bent;
wherein the shape of the connection line at the position where the connection line is electrically connected with the data line comprises an S-shape or a folded line shape; or wherein the connection line at the position where the connection line is electrically connected with the data line comprises a plurality of first portions and a plurality of second portions, the plurality of first portions and the plurality of second portions are alternately connected with each other, and each first portion is perpendicular to each second portion.

17. The array substrate according to claim 1, wherein the connection line comprises a main connection line, a first auxiliary connection line electrically connected with the data line, and a second auxiliary connection line electrically connected with the pad; and
the main connection line is provided with a first compensating portion at a position where the main connection line is connected with the first auxiliary connection line, and a second compensating portion at a position where the main connection line is connected with the second auxiliary connection line.

18. The array substrate according to claim 1, further comprising a plurality of dummy gate driver units disposed outside the display area and a plurality of dummy thin-film transistors electrically connected with output ends of the dummy gate driver units.

19. The array substrate according to claim 18, further comprising multiple first transistors in the display area;
wherein, along the second direction, a density of the dummy thin-film transistors is approximately equal to a density of the first transistors in the display area; and
along the first direction, a density of dummy thin-film transistors in the bonding area is greater than a density of the first transistors in the display area.

20. A display panel comprising the array substrate according to claim 1.
